(19) United States
(12) Patent Application Publication
(10) Pub. No.: US 2007/0023901 A1
(43) Pub. Date: Feb. 1, 2007

(54) Microelectronic bond pad

(76) Inventors: Gerard Mahoney, Hillsboro, OR (US); Matthew Essar, Hillsboro, OR (US); Walter Wohlmuth, Hillsboro, OR (US); Wayne Struble, Hillsboro, OR (US)

Correspondence Address: Joe Pugh, TriQuint Semiconductor, Inc., 2300 N.E. Brookwood Parkway, Hillsboro, OR, 97124, US

(21) Appl. No.: 11/192,915

(22) Filed: Jul. 29, 2005

(51) Int. Cl. H01L 23/48

(52) U.S. Cl. 257/736

(57) ABSTRACT

One embodiment of an integrated circuit includes a substrate, an electrical device positioned above the substrate, and a bond bad positioned above and aligned along a vertical axis with the electrical device such that the electrical device is positioned between the substrate and the bond pad.

### BACKGROUND

Integrated circuits (ICs) may include bond pads so that electrical connectors and/or conductors, such as bonding wires and/or metallic bumps, may be connected to electrical devices within the IC. Bond pads are spaced horizontally, i.e., in the same plane, from the electrical devices of the IC such that the bond pads are positioned in a periphery of the IC. Accordingly, the bond pads utilize valuable surface area and allow limited flexibility of positioning of the bond pads on the IC. It may be desirable to form a bond pad that utilizes less surface area on the IC and which allows flexibility in positioning of the bond pad on the IC.

### BRIEF DESCRIPTION OF THE DRAWINGS

FIG. 1 is a schematic cross-sectional side view of a prior art integrated circuit including a bond pad positioned next to an electrical device.

FIG. 2 is a schematic cross-sectional side view of one embodiment of an integrated circuit including a bond pad of the present invention positioned above an electrical device, and having a bonding wire connected to the bond pad.

FIG. 3 is a schematic cross-sectional side view of one embodiment of an integrated circuit including a metallic bump of the present invention positioned above an electrical device, and having a metallic bump connected to the bond pad.

### DETAILED DESCRIPTION OF THE DRAWINGS

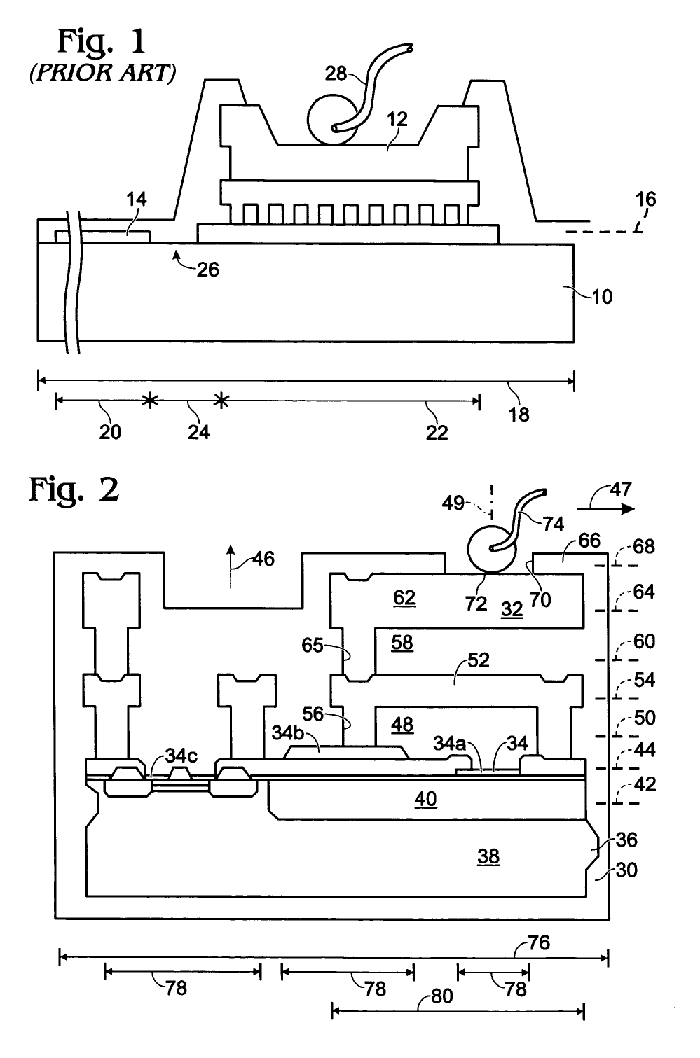

FIG. 1 is a schematic cross-sectional side view of a prior art integrated circuit 10 including a bond pad 12 positioned next to an electrical device 14. Bond pad 12 is positioned next to electrical device 14, as measured in plane 16, such that integrated circuit 10 (IC) defines a width 18 including both a width 20 of device 14 and a width 22 of bond pad 12. Accordingly, a footprint or a surface area of IC 10, which may be defined by the width 18 of IC 10 multiplied by the length (shown in end view in FIG. 1) includes width 22 of bond pad 12. Bond pad 12 may be spaced a horizontal distance 24 from electrical device 14 such that a buffer region 26 physically and thermally protects device 14 during connection of an electrical connector, such as a metallic wire 28, to bond pad 12. Positioning of bond pad 12 horizontally in plane 16 with respect to electrical device 14 utilizes valuable surface area on IC 10 and allows limited flexibility of positioning of the bond pads 12 on the IC 10.

FIG. 2 is a schematic cross-sectional side view of one embodiment of an integrated circuit 30 including a bond pad 32 of the present invention positioned above one or more electrical devices 34. In the embodiment shown, electrical device 34a is a nickel chromium resistor and electrical device 34b is a metal insulator metal (MIM) capacitor. In other embodiments, bond pad 32 may be positioned vertically above a layer that contains any type of electrical device 34 on an integrated circuit as may be desired for a particular application.

In particular, IC 10 includes a stacked layer arrangement 36 including a device support or a substrate layer 38, such as a gallium arsenide substrate. An isolation implant layer 40 may then be formed on or within substrate 38. The isolation damage implant layer 40 may be formed of Aluminum or Boron ions or other suitable elements. One or more electrical devices 34 may then be formed on substrate 38 or on isolation implant layer 40, such that the substrate forms a first plane 42 and the electrical devices 34 form a second plane 44 positioned generally parallel to and vertically above first plane 42 in an upward direction 46. The term upward is used for ease of illustration. However, the integrated circuit may be oriented in any direction wherein the layers of the stacked arrangement are successively built on the preceding layer there beneath. A lower dielectric layer 48 may then be formed on electrical device 34, wherein lower dielectric layer 48 forms a third plane 50 positioned generally parallel to and vertically above second plane 44 as measured along direction 46. Lower dielectric layer 48 may be a BCB spin-on dielectric.

A first metal layer 52 may then be formed on lower dielectric layer 48, wherein first metal layer 52 forms a fourth plane 54 positioned generally parallel to and vertically above third plane 50 as measured along direction 46. Lower dielectric layer 48 may include vias or trenches 56 such that first metal layer 52 may extend downwardly through lower dielectric layer 48 and electrically contact one or more of electrical devices 34. A second or upper dielectric layer 58 may then be formed on first metal layer 52, wherein upper dielectric layer 58 forms a fifth plane 60 positioned generally parallel to and vertically above fourth plane 54, as measured along direction 46. A second or upper metal layer 62 may then be formed on upper dielectric layer 58, wherein upper metal layer 62 forms a sixth plane 64 positioned generally parallel to and vertically above fifth plane 60, as measured along direction 46. Upper dielectric layer 58 may include vias or trenches 65 such that second metal layer 62 may extend downwardly through upper dielectric layer 58 and electrically contact first metal layer 52.

A passivation or third dielectric layer 66 may then be formed on upper metal layer 62, wherein passivation dielectric layer 66 forms a seventh plane 68 positioned generally parallel to and vertically above sixth plane 64, as measured along direction 46. Passivation dielectric layer 66 may include a trench or a via 70 such that a portion 72 of second metal layer 62 is exposed. This exposed portion 72 of second metal layer 62 may define the bond pad 32 of integrated circuit 10. A conductive connector, such as an electrically conductive wire 74 may be bonded to exposed portion 72 of second metal layer 62.

Electrical devices 34 may be physically and thermally protected from the bonding operation, wherein wire 74 is bonded to bond pad 32, by upper dielectric layer 58. Accordingly, rather than being spaced outwardly in a horizontal direction 47 from electrical devices 34 in plane 44, bond pad 32 is spaced upwardly from electrical device 34 in a direction 46 and positioned directly above device 34, i.e., aligned with device 34 along a vertical axis 49.

Accordingly, wire 74 is bonded to bond pad 32, wherein bond pad 32 is positioned above one or more electrical devices 34. A width 76 of IC 10, therefore, may be defined by a width 78 of multiple devices 34, as measured in plane 44. In other words, second metal layer 62, which includes bond pad 32, is not positioned within plane 44, such that width 76 of IC 10 is not dependent upon, and is not increased by, width 80 of second metal layer 62. Positioning of bond pad 32 above electrical devices 34, therefore, may reduce the footprint or surface area of IC 10, which may result in increased working speeds of the IC and lower manufacturing costs. Additionally, positioning of bond pad 32 in a plane 64 different from plane 44 of electrical devices 34 allows flexibility in positioning of bond pad 32, i.e., positioning of bond pad 32 in plane 64 allows bond pad 32 to be positioned in many more positions than would be available if bond pad 32 were positioned in plane 44 with electrical devices 34.

The process variables will now be described. Lower and upper dielectric layers 48 and 58 may be formed of Benzocyclobutene (BCB) spin-on dielectrics used to electrically isolate metal interconnect layers from underlying circuitry. In one embodiment the spin-on dielectrics may be deposited as a viscous liquid onto a spinning wafer substrate. The thickness of the dielectric may be determined by the spin speed of the wafer substrate at the time of dispense. In one embodiment of the present invention, upper and lower dielectric layers 48 and 58 are 1 and 2.8 um (microns), respectively, but may be deposited in a thickness range of 1 to 10 um. The dielectric layers may be cured after deposit by heating in an oven at 300° C. The resulting dielectric layer may take on a glass-like hardness.

Via holes 56, 65 and/or 70 may be defined in their respective cured dielectric layer for the purpose of making connections between the metal interconnect layers and to the underlying circuitry. The vias are fabricated by defining a photoresist pattern on the corresponding dielectric layer and etching away the unprotected areas of dielectric material in a high density plasma etching system using, in one example embodiment, a sulfurhexafluoride plus oxygen (SF₆+0₂) plasma or other suitable fluorine containing gas.

One or more bond pads 32 may be defined in upper metal layer 62. Both lower and upper metal layers 52 and 62 may be fabricated by electrochemical plating gold (Au) on top of a suitable field metal. The Au thicknesses used in one embodiment of layers 52 and 62 may be 2 and 4 um, respectively. In one embodiment, the field metal may be a metal stack of Titanium-Tungsten/Gold/Titanium (TiW/Au/Ti) with layer thicknesses of 500 Å (Angstroms), 1060 Å, and 1000 Å, respectively. However, other field metals and thicknesses may be utilized.

The metal interconnect features within vias 56, 65 and/or 70 may be defined by a photoresist pattern on top of the field metal. The top titanium layer of the field metal may be removed in the unprotected areas of the field metal and Au plated in the features. The top Titanium may then be removed by etching in a reactive ion etcher using a Carbontetraflouride+Nitrogentrifluoride+Argon (CF4+NF3+Ar) plasma, for example. The photoresist, used to define the interconnect features, may then be removed after the plating operation by exposing the photoresist to an oxygen plasma.

The field metal stack left between the plated Au features may then be removed by etching in a high-density plasma etching system. The top Titanium layer of the field metal may be etched in SF₆ or another suitable fluorine containing gas. The gas in the plasma etching system may then be switched to Ar, for example, and the Au layer removed by sputtering. The bottom TiW layer may then be etched away by switching the gas back to SF₆ or another suitable fluorine containing gas.

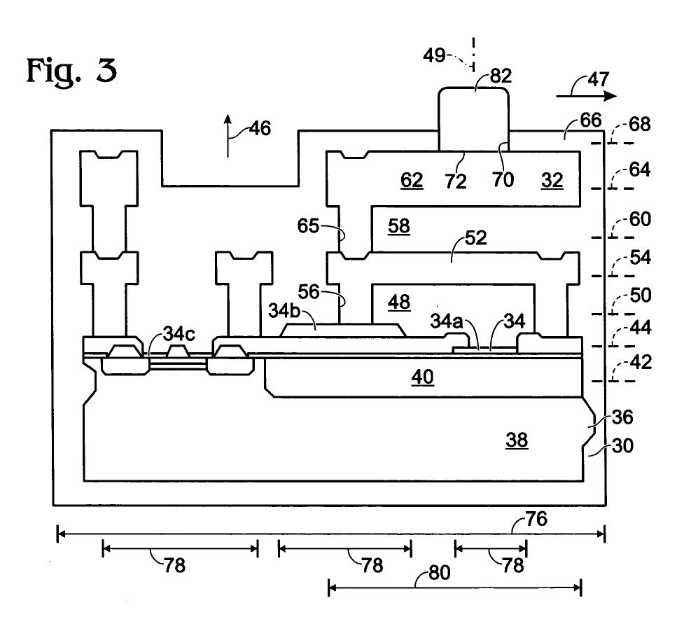

FIG. 3 is a schematic cross-sectional side view of one embodiment of an integrated circuit 30 including a metallic bump 82 of the present invention positioned above an electrical device 34 and connected to bond pad 32 through exposed region 72 of passivation dielectric layer 66. Metallic bump 82 may be utilized for heat dissipation from electrical device 34 or for flip chip bonding of IC 10 to a substrate (not shown).

Other variations and modifications of the concepts described herein may be utilized and fall within the scope of the claims below.

We claim:

1. An integrated circuit, comprising:
a substrate;
an electrical device positioned above said substrate; and
a bond bad positioned above and aligned along a vertical axis with said electrical device such that said electrical device is positioned between said substrate and said bond pad.

2. The circuit of claim 1 further comprising a dielectric layer positioned between said bond pad and said electrical device.

3. The circuit of claim 2 wherein said dielectric layer has a thickness in a range of 2.5 to less than 8 microns.

4. The circuit of claim 2 further comprising a metal positioned between said dielectric layer and said device.

5. The circuit of claim 4 further comprising a second dielectric layer positioned between said metal and said device.

6. The circuit of claim 1 wherein said bond pad is manufactured of gold.

7. The circuit of claim 1 further comprising an electrical connector connected to said bond pad.

8. The circuit of claim 7 wherein said electrical connector is chosen from one of a metallic wire and a metallic bump.

9. The circuit of claim 2 wherein said dielectric layer comprises a spin-on deposited dielectric layer that is thermally cured at a temperature above 300 degrees Celsius.

10. The circuit of claim 5 wherein said second dielectric layer has a thickness in a range of 0.5 to 1.5 microns.

11. The circuit of claim 1 further comprising a passivation dielectric layer positioned above said bond pad, said passivation dielectric layer including a via extending through said passivation dielectric layer to said bond pad.

12. The circuit of claim 1 wherein said electrical device is chosen from one of a resistor, a capacitor and a transistor.

13. The circuit of claim 9 wherein said spin-on deposited dielectric layer comprises a BCB spin-on dielectric.

14. The circuit of claim 1 wherein said circuit defines a footprint excluding a surface area devoted solely to a bond pad.

15. A method of manufacturing an integrated circuit, comprising:
forming a microelectrical device on a support;
forming a dielectric layer above said microelectrical device; and
forming an electrical connection region above said dielectric layer such that said microelectrical device is positioned in between and vertically aligned with said support and said electrical connection region.

16. The method of claim 15, prior to forming said dielectric layer, forming a lower dielectric layer on said microelectrical device, and then forming a first metal layer on said lower dielectric layer, and wherein said dielectric layer is formed on said first metal layer.

17. The method of claim 15 wherein said support defines a first plane, said microelectrical device defines a second plane, and said electrical connection region forms a third plane, wherein said first, second and third planes are all parallel to one another.

18. The method of claim 15 further comprising forming a passivation dielectric layer on said electrical connection region, said passivation dielectric layer including a recess exposing a portion of said electrical connection region through said passivation dielectric layer.

19. The method of claim 18 wherein said passivation dielectric layer is formed of silicon nitride.

20. The method of claim 15 wherein said dielectric layer defines a thickness of less than 8 microns.

21. An integrated circuit, comprising:
means for supporting an electrical device;
an electrical device supported on said means for supporting; and
means for electrically connecting to said electrical device, said means for electrically connecting positioned above said electrical device such that said electrical device is positioned directly between said means for supporting and said means for electrically connecting.

22. The circuit of claim 21 wherein said means for supporting comprises a gallium arsenide substrate.

23. The circuit of claim 21 wherein said electrical device is chosen from one of a nickel chromium resistor, a MIM capacitor, a MESFET transistor, a pHEMT transistor, and a HBT transistor.

24. The circuit of claim 21 wherein said means for electrically connecting is a gold bond pad.

25. The circuit of claim 21 further comprising an electrical connector connected to said means for electrically connecting, said electrical connector chosen from one of a gold bond wire and a copper bump.

26. A method of manufacturing an integrated circuit, comprising:
forming a microelectrical device layer on a support;
forming a dielectric layer vertically above said microelectrical device layer; and
forming an electrical connection directly, vertically above said dielectric layer.

27. The method of claim 26 wherein said step of forming a microelectrical device layer on a support comprises a photolithographic deposition process.

28. The method of claim 26 wherein said forming a dielectric layer comprises depositing said dielectric layer by chemical vapor deposition.

29. The method of claim 26 wherein said forming an electrical connection layer comprises depositing said electrical connection layer by chemical vapor deposition.
